(19) United States
(12) Patent Application Publication
(10) Pub. No.: US 2026/0162935 A1
(43) Pub. Date: Jun. 11, 2026

(54) THERMAL SOLUTIONS FOR HIGH FREQUENCY AND HIGH POWER TRANSMISSION

(71) Applicant: Applied Materials, Inc., Santa Clara, CA (US)

(72) Inventors: ADAM FISCHBACH, Campbell, CA (US); THAI CHENG CHUA, Cupertino, CA (US)

(21) Appl. No.: 18/977,797

(22) Filed: Dec. 11, 2024

(51) Int. Cl. H01J 37/32

(52) U.S. Cl. CPC H01J 37/32082; H01J 2237/002

(57) ABSTRACT

Embodiments described herein relate to an apparatus that includes a housing, and a core within the housing. In an embodiment, a channel is set into an outer surface of the core, and a first hole passes through the core. In an embodiment, the apparatus further includes an inlet through the housing, where the inlet is fluidly coupled to the channel, and an outlet through the housing, where the outlet is fluidly coupled to the channel. In an embodiment, the apparatus further includes a dielectric plug within the first hole, where a second hole passes through the dielectric plug.

### BACKGROUND

### 1) Field

Embodiments relate to the field of semiconductor manufacturing and, in particular, to thermal solutions for high frequency and high power plasma sources.

### 2) Description of Related Art

The electrical components of a high frequency plasma system are susceptible to heat. For example, the high frequency plasma source and cables (e.g., coaxial cables or the like) may be damaged or degraded by the heat generated by the system. Particularly, heat generated by the plasma or heat from a heated chamber may be transferred from the antenna back towards the electrical components that drive the plasma. In some instances the heat generated by the system is sufficient to melt connections between the source of high frequency power and the antenna.

### SUMMARY

Embodiments described herein relate to an apparatus that includes a housing, and a core within the housing. In an embodiment, a channel is set into an outer surface of the core, and a first hole passes through the core. In an embodiment, the apparatus further includes an inlet through the housing, where the inlet is fluidly coupled to the channel, and an outlet through the housing, where the outlet is fluidly coupled to the channel. In an embodiment, the apparatus further includes a dielectric plug within the first hole, where a second hole passes through the dielectric plug.

Embodiments described herein relate to an apparatus that includes an upper housing with an interior tube, and a lower housing coupled to the upper housing, where the lower housing includes an opening through the lower housing, and the interior tube passes through the opening. In an embodiment, the upper housing and the lower housing define a channel around the interior tube, and a dielectric plug is within the interior tube. In an embodiment, a hole passes through the dielectric plug.

Embodiments described herein relate to an apparatus that includes a solid state high frequency power source, and an applicator for propagating high frequency electromagnetic radiation from the solid state high frequency power source. In an embodiment, the apparatus further includes a thermal break coupled between the solid state high frequency power source and the applicator. In an embodiment, the thermal break includes a housing with a fluidic channel, and a dielectric plug within the housing, where the dielectric plug is surrounded by the fluidic channel. In an embodiment, a metallic rod is provided through the dielectric plug, where the metallic rod electrically couples the solid state high frequency power source to the applicator.

### BRIEF DESCRIPTION OF THE DRAWINGS

FIG. 1A is a cross-sectional illustration of a high frequency emission module with a thermal break between the power source and the applicator, in accordance with an embodiment.

FIG. 1B is a cross-sectional illustration of a thermal break with a spiral cooling channel with a stepped dielectric plug, in accordance with an embodiment.

FIG. 1C is a cross-sectional illustration of a thermal break with a spiral cooling channel and a tapered dielectric plug, in accordance with an embodiment.

FIG. 2A is a cross-sectional illustration of a high frequency emission module with a thermal break between the power source and the applicator, in accordance with an additional embodiment.

FIG. 2B is a cross-sectional illustration of a thermal break with a cooling channel and a mounting bracket, in accordance with an embodiment.

FIG. 2C is a plan view illustration of a thermal break with a cooling channel and a mounting bracket, in accordance with an embodiment.

FIG. 3A is a cross-sectional illustration of a processing tool that comprises a modular high frequency emission source with a plurality of high frequency emission modules that each include a thermal break with a spiral cooling channel, in accordance with an embodiment.

FIG. 3B is a cross-sectional illustration of a processing tool that comprises a modular high frequency emission source with a plurality of high frequency emission modules that each include a thermal break with a cooling channel and a mounting bracket, in accordance with an embodiment.

FIG. 4 is a block diagram of a modular high frequency emission module, in accordance with an embodiment.

FIG. 5A is a plan view of an array of applicators that may be used to couple high frequency radiation to a processing chamber, in accordance with an embodiment.

FIG. 5B is a plan view of an array of applicators that may be used to couple high frequency radiation to a processing chamber, in accordance with an additional embodiment.

FIG. 5C is a plan view of an array of applicators and a plurality of sensors for detecting conditions of a radiation field and/or a plasma, in accordance with an embodiment.

FIG. 5D is a plan view of an array of applicators that are formed in two zones of a multi-zone processing tool, in accordance with an embodiment.

FIG. 6 illustrates a block diagram of an exemplary computer system that may be used in conjunction with a high frequency plasma tool, in accordance with an embodiment.

### DETAILED DESCRIPTION

Embodiments described herein include thermal solutions for high frequency and high power plasma sources. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, plasma processing tools that utilize high frequency plasma sources are susceptible to degradation or damage resulting from heat transfer from the plasma and/or the chamber to the power source and the cabling between the power source and the antenna. In some instances, it has even been observed that the thermal load causes the cabling to melt. Accordingly, embodiments disclosed herein include a thermal break that thermally isolates the cabling and the solid state electronics of the power source from the thermal load supplied by a plasma and/or the chamber.

In some embodiments, the thermal break is located between the applicator (e.g., an antenna) and solid state electronics of the processing tool. For example, the solid state electronics may be electrically coupled to the thermal break by a coaxial cable, and the thermal break may be directly coupled to the antenna. In addition to providing thermal isolation between components of the processing tool, the thermal break also provides an electrical coupling from the coaxial cable to the antenna. In some embodiments, the thermal break may also function as an impedance matching element in order to allow for efficient transfer of power to the plasma. Accordingly, the impedance matching and the thermal regulation may be implemented in a single component (i.e., the thermal break). This reduces the complexity and provides for a compact construction.

Some existing solutions for providing thermal solutions between the applicator and the solid state electronics have included air-cooled or otherwise passive thermal approaches. However, when high powered systems are used, passive approaches may not be sufficient to dissipate the high amount of thermal energy. Accordingly, embodiments disclosed herein may include liquid cooled solutions. In such an embodiment, an electrically conductive path is surrounded by a dielectric plug, and the dielectric plug is in close proximity to a fluidic channel. A liquid may flow through the channel in order to actively remove thermal energy from the system.

In one embodiment, the thermal break comprises an outer housing and an inner core. The inner core may have a spiral channel formed into an outer surface, and the outer housing seals the spiral channel. In an embodiment, a hole through the inner core may be filled with a dielectric plug, and a metallic rod may pass through the dielectric plug to provide an electrically conductive path between a coaxial cable that is coupled to the solid state electronics and the applicator. The metallic rod may be inserted into the applicator.

In another embodiment, the thermal break may include a two piece housing. The two piece housing may include an upper portion that includes a tube that passes through a hole in a lower housing. The upper housing and the lower housing are coupled together (e.g., by welding) in order to form a fluidic channel around the tube. The dielectric plug and metallic rod may be inserted into an interior of the tube.

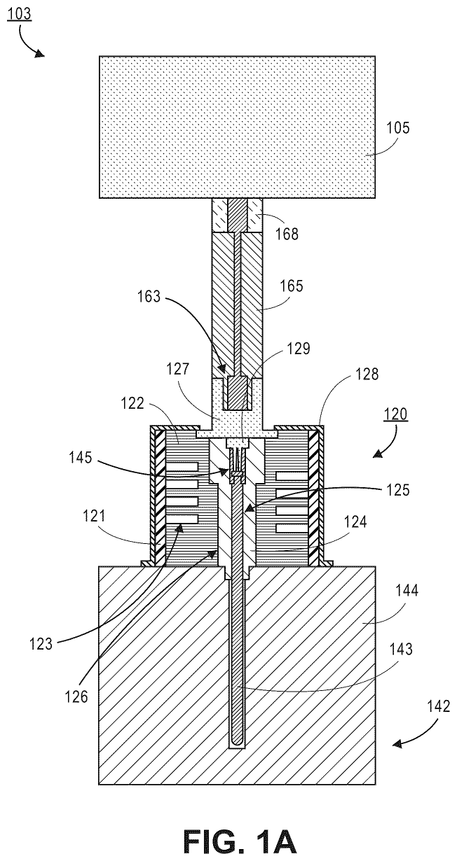

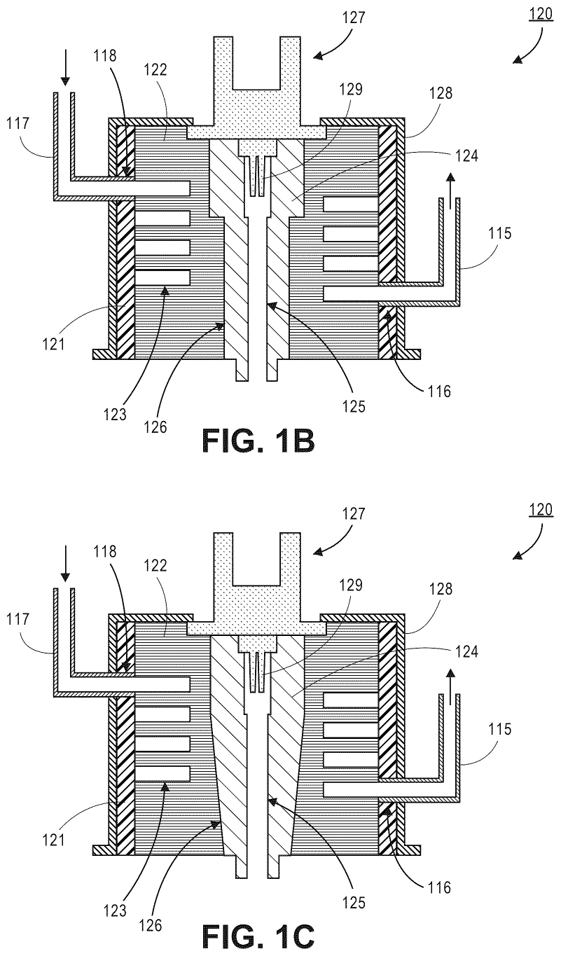

Referring now to FIG. 1A, a cross-sectional illustration of a high frequency emission module 103 is shown, in accordance with an embodiment. In an embodiment, the high frequency emission module 103 may comprise a solid state power source 105, a thermal break 120, and an applicator 142.

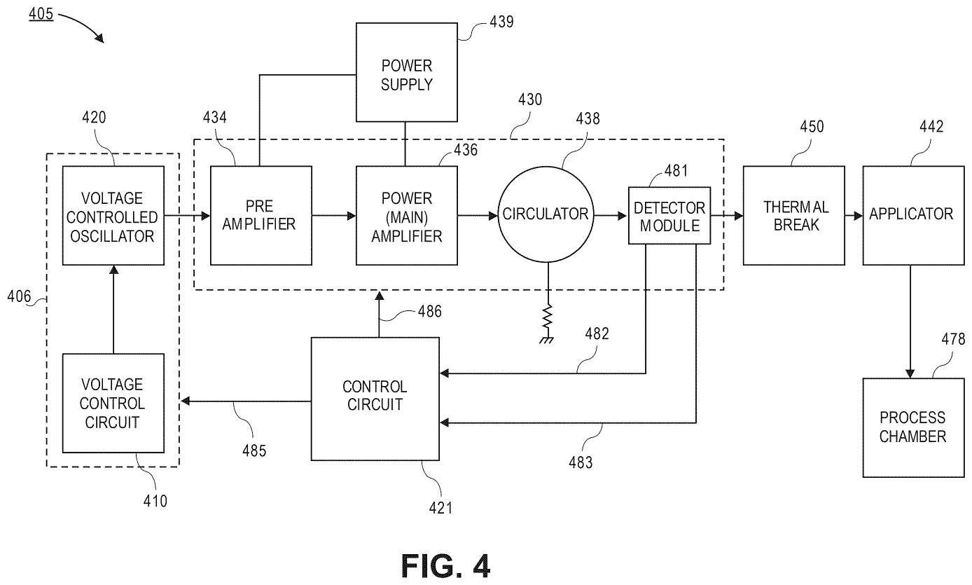

The solid state power source 105 may comprise a plurality of sub-components, such as an oscillator, amplifiers, and other circuitry blocks. A more detailed description of the solid state power source 105 is provided below with respect to FIG. 4. In an embodiment, the power source 105 provides high frequency electromagnetic radiation to the applicator 142. As used herein, “high frequency” electromagnetic radiation may include radio frequency radiation, very-high frequency radiation, ultra-high frequency radiation, and microwave radiation. “High frequency” may refer to frequencies between 0.1 MHz and 300 GHz.

In an embodiment, the applicator 142 may comprise a dielectric body 144 with a cavity into which an antenna 143 is disposed. For example, the antenna 143 may comprise a conductive line (e.g., a monopole) that extends into the dielectric body 144. In some embodiments, the antenna 143 is in direct contact with the dielectric body 144. In other embodiments, the cavity is larger than the antenna 143, and the antenna 143 is spaced away from surfaces of the dielectric body 144. In some instances, the antenna 143 may be referred to as a rod or a metallic rod. The antenna 143 may comprise any suitable electrically conductive material. For example, the antenna 143 may comprise copper or an alloy of copper and beryllium.

In an embodiment, the applicator 142 may be electrically coupled to the thermal break 120. The thermal break 120 may comprise an outer housing 121 and core 122. The outer housing 121 and the core 122 may comprise a thermally conductive material, such as metal. In one embodiment, the outer housing 121 and the core 122 comprise different materials. For example, the outer housing 121 may comprise a stainless steel, and the core 122 may comprise aluminum. In an embodiment, a channel 123 may be formed into an outer surface of the core 122. For example, the channel 123 may be a spiral channel that wraps around a perimeter of the core 122.

In an embodiment, the channel 123 of the core 122 may be sealed by the outer housing 121. While not shown, a gasket of the like may be used to provide a fluidic seal that prevents a cooling fluid (not shown) from leaking out of the channel 123. In an embodiment, the thermal break 120 may comprise an inlet and an outlet (described in greater detail below) that allows for a cooling fluid (e.g., water, oil, etc.) to flow through the channel 123 in order to dissipate thermal energy from the thermal break 120. While shown as discrete components, other embodiments may include an outer housing 121 and a core 122 that are formed as a monolithic structure. For example, a 3D printing process may be used to form a single structure with an internal channel 123.

In an embodiment, the core 122 may comprise a first hole 126. The first hole 126 may pass through a height of the core 122. In the illustrated embodiment, the first hole 126 has a non-uniform diameter along the height of the core 122. For example, the first hole 126 in FIG. 1A has a stepped profile. Though, the shape of the first hole 126 may be any suitable shape.

In an embodiment, at least a portion of the first hole 126 may be filled with a dielectric plug 124. The dielectric plug 124 may surround the antenna 143 (which may extend up from the applicator 142). The dielectric plug 124 may be any suitable dielectric material. The material of the dielectric plug 124 may be chosen in order to set a desired impedance for the thermal break 120. For example, the dielectric plug 124 may comprise polytetrafluoroethylene (PTFE), polyether ether ketone (PEEK), polyimide, perfluoroalkoxy alkane (PFA), polyetherimide (PEI), polyvinylidene fluoride (PVDF), or the like. The impedance of the high frequency emission module 103 may also be tuned through the selection of one or more of the diameter of the dielectric body 144, selection of material for the dielectric body 144, a diameter of the antenna 143, a length of the antenna 143, and/or the like.

In an embodiment, an end 145 of the antenna 143 may be press fit into a fitting 129 of a connector 127 at a top of the thermal break 120. That is, the antenna 143 may pass through a second hole 125 that passes through a height of the dielectric plug 124. The connector 127 electrically couples a coaxial cable 165 from the solid state power source 105 to the antenna 143. The use of a press fitting at the end 145 of the antenna 143 allows for different length antennas 143 to be used with the thermal break 120 for different applications and/or for tuning to different impedances. In an embodiment, a diameter and/or profile of the dielectric plug 124 and/or a length and/or diameter of the antenna 143 may be chosen in order to set a desired impedance for the high frequency emission module 103.

In an embodiment, the thermal break 120 may also comprise a mounting bracket 128. The mounting bracket 128 may be placed over the outer housing 121 and be used to mechanically couple the thermal break 120 to the applicator 142. While shown as being in direct contact with the applicator 142, other embodiments may include the thermal break 120 being spaced away from the applicator 142.

In an embodiment, cabling and connectors (e.g., the coaxial cable 165 and connectors 163 and 168) between the thermal break 120 and the solid state power source 105 are protected from thermal energy dissipated by the system. As such, a high power and high frequency emission module 103 may be used without the risk of damage from high amounts of thermal energy generated by the applicator 142 during operation.

Referring now to FIG. 1B, a cross-sectional illustration of a portion of the thermal break 120 is shown, in accordance with an additional embodiment. In an embodiment, the view of the thermal break 120 illustrates an inlet 118 and an outlet 116 that may be used to flow a cooling fluid (not shown) through the channel 123. In an embodiment, the inlet 118 and the outlet 116 may pass through the outer housing 121 in order to allow pipes 117 and 115 to fluidly couple with the channel 123. In an embodiment, the cooling fluid may enter the channel 123 towards a top of the thermal break 120, flow through the channel 123 (which wraps around the core 122 out of the plane of FIG. 1B), and exit the channel 123 towards a bottom of the thermal break 120.

In FIG. 1B the antenna 143 is omitted. That is, the thermal break 120 may be a component that is interchangeable between different plasma systems and/or used for different processing regimes. The different applications and/or processing regimes may be accommodated by choosing different antenna structures (e.g., diameters, lengths, materials, etc.). Since the antenna 143 can be press fit into the thermal break 120, the thermal break 120 can be easily altered in order to be used for the different systems and/or conditions.

Referring now to FIG. 1C, a cross-sectional illustration of a thermal break 120 is shown, in accordance with an additional embodiment. In an embodiment, the thermal break 120 in FIG. 1C is similar to the thermal break 120 in FIG. 1B, with the exception of the dielectric plug 124. Instead of having a stepped profile, the dielectric plug 124 may have an outer sidewall (which is adjacent to the first hole 126) that has a tapered diameter. The variation of the diameter of the dielectric plug 124 may be chosen in order to provide a desired impedance characteristic to the thermal break 120.

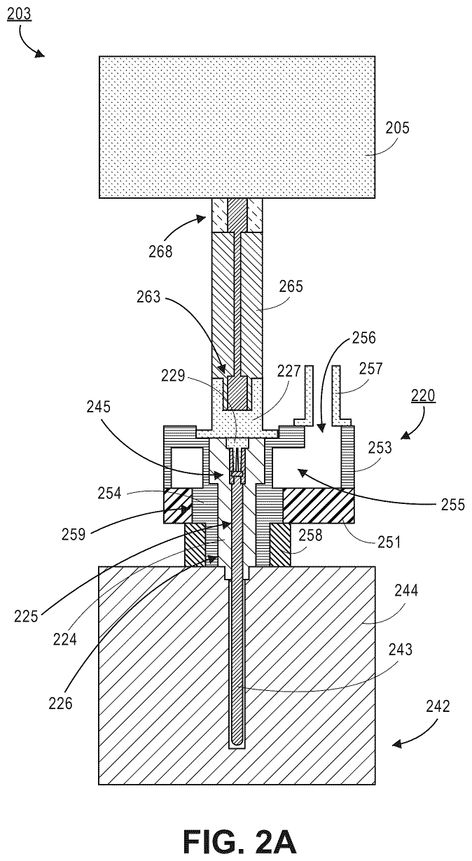

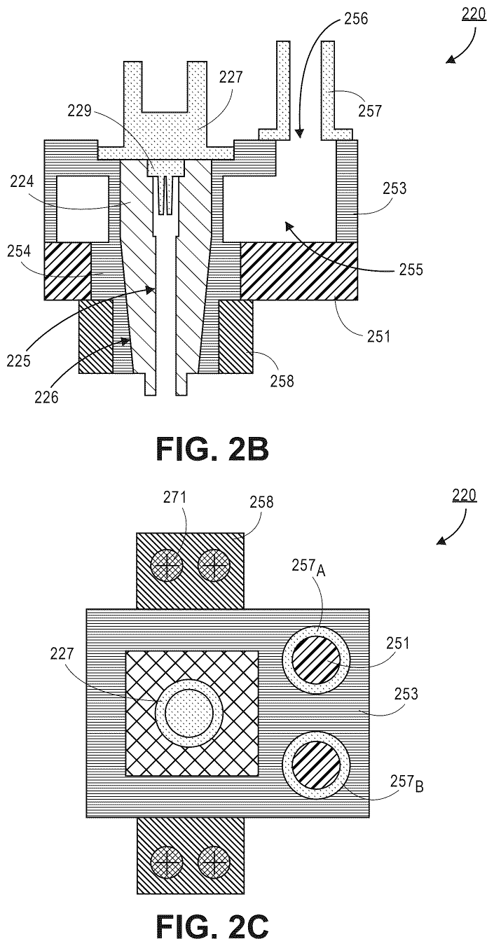

Referring now to FIG. 2A, a cross-sectional illustration of a high frequency emission module 203 is shown, in accordance with an embodiment. In an embodiment, the high frequency emission module 203 may comprise a solid state power source 205, a thermal break 220, and an applicator 242.

The solid state power source 205 may be similar to the solid state power source 105 described in greater detail herein. Similarly, the applicator 242 may be similar to the applicator 142 described in greater detail herein. For example, the applicator 242 may comprise a dielectric body 244 with a cavity into which an antenna 243 is inserted. In some instances, the antenna 243 may be referred to as a rod or a metallic rod.

In an embodiment, the applicator 242 may be electrically coupled to the thermal break 220. The thermal break 220 may comprise an upper housing 253 and a lower housing 251. In an embodiment, the upper housing 253 and the lower housing 251 may be coupled together. For example, the upper housing 253 may be welded to the lower housing 251. In an embodiment, the upper housing 253 and the lower housing 251 may define a channel 255. The channel 255 may surround a tube 254 that extends through a hole 259 in the lower housing 251.

In an embodiment, the tube 254 and the upper housing 253 may comprise a monolithic structure. Though, in other embodiments, the tube 254 and the upper housing may comprise discrete components. Further, while the upper housing 253 and the lower housing 251 are described as discrete components, other embodiments may include a monolithic housing. For example, a 3D printing process may be used to form a housing with an internal channel 255 and tube 254 in some embodiments.

In an embodiment, the channel 255 at least partially surrounds the tube 254. For example, a cooling fluid may enter the channel 255 through a pipe 257 into an inlet 256, flow around the tube 254 and exit the channel 255 through an outlet (which is out of the plane of FIG. 2A). As such, a cooling fluid (e.g., water, oil, etc.) may flow around an exterior of the tube 254 in order to cool a dielectric plug 224 and antenna 243 that are surrounded by an interior surface 226 of the tube 254. The antenna 243 may be inserted into a hole 225 that passes through a height of the dielectric plug 224.

In an embodiment, a diameter of the dielectric plug 224 may be non-uniform through its height. For example, the dielectric plug 224 in FIG. 2A includes a stepped profile. The dielectric plug 224 may comprise any suitable dielectric material, such as polytetrafluoroethylene (PTFE), polyether ether ketone (PEEK), polyimide, perfluoroalkoxy alkane (PFA), polyetherimide (PEI), polyvinylidene fluoride (PVDF), or the like. The material composition and/or dimensions of the dielectric plug 224 may be chosen in order to set a desired impedance for the thermal break 220 in some embodiments. In an embodiment, the antenna 243 may have an end 245 that is press fit into a fitting 229 of a connector 227. The use of an antenna 243 that is press fit to the connector 227 may allow for many different applications and/or processing regimes, similar to other embodiments described in greater detail herein.

In an embodiment, the thermal break 220 may also comprise a mounting bracket 258 that is provided between the thermal break 220 and the applicator 242. The mounting bracket 258 may comprise a thermally insulating material (e.g., a polymer such as polyether ether ketone (PEEK)) in order to provide improved thermal isolation from the mounting surface for applications with a high temperature lid and/or pedestal. Though, other embodiments may include a thermally conductive mounting bracket 258 (e.g., aluminum) to assist with cooling the plasma source for temperature stabilization purposes. In the illustrated embodiment, the mounting bracket 258 is in direct contact with the dielectric body 244. Though, in other embodiments, the mounting bracket 258 may be spaced away from the dielectric body 244.

In an embodiment, cabling and connectors (e.g., the coaxial cable 265 and connectors 263 and 268) between the thermal break 220 and the solid state power source 205 are protected from thermal energy dissipated by the system. As such, a high power and high frequency emission module 203 may be used without the risk of damage from high amounts of thermal energy generated by the applicator 242 during operation.

Referring now to FIG. 2B, a cross-sectional illustration of a thermal break 220 is shown, in accordance with an additional embodiment. In an embodiment, the thermal break 220 in FIG. 2B is similar to the thermal break 220 in FIG. 2A, with the exception of the dielectric plug 224. Instead of having a stepped profile, the dielectric plug 224 may have a non-uniform diameter (which is adjacent to the sidewall surface 226 of the tube 254) that is tapered. The variation of the diameter of the dielectric plug 224 may be chosen in order to provide a desired impedance characteristic to the thermal break 220.

Referring now to FIG. 2C, a plan view illustration of a thermal break 220 is shown, in accordance with an embodiment. The thermal break 220 in FIG. 2C may be similar to the thermal break 220 in FIG. 2B. As shown, the connector 227 may be provided over the upper housing 253. Further, a first pipe 257_{A} may function as a cooling fluid inlet, and a second pipe 257_{B} may function as a cooling fluid outlet. The mounting bracket 258 below the lower housing 251 may include fasteners 271 (e.g., pins, screws, bolts, magnets, etc.) that are configured to mount the thermal break 220 to the larger system.

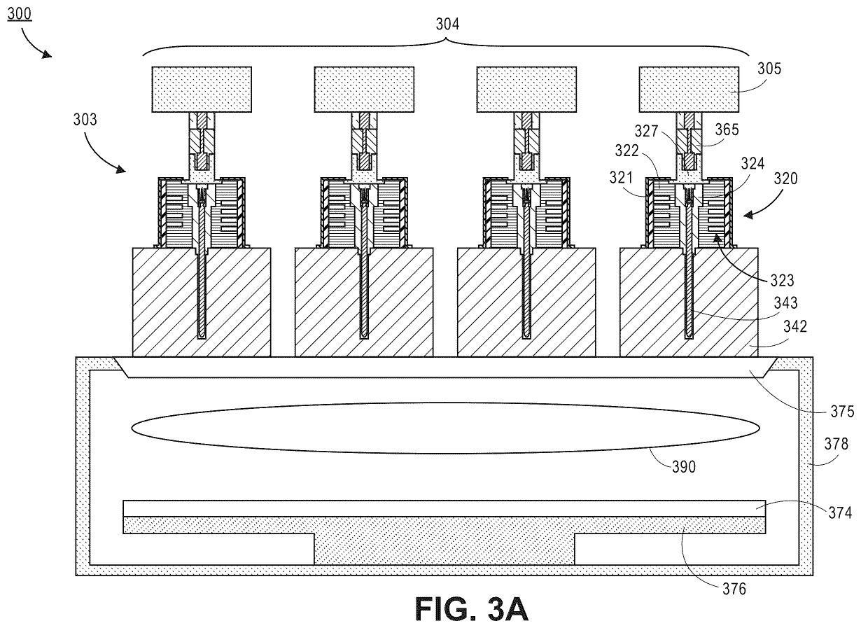

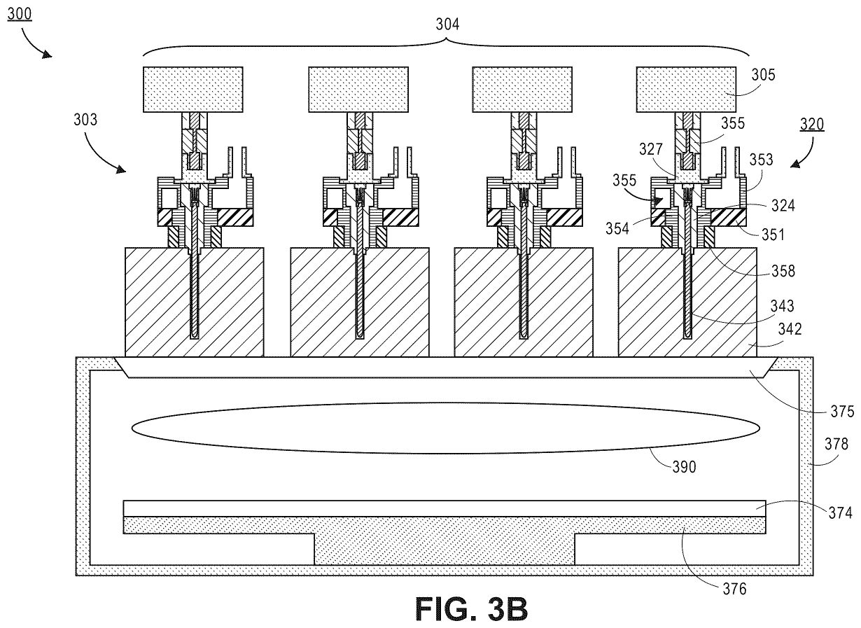

Referring now to FIG. 3A, a cross-sectional schematic illustration of a processing system 300 with a modular high frequency emission source 304 is shown, in accordance with an embodiment. In an embodiment, the modular high frequency emission source 304 may comprise a plurality of high frequency emission modules 303. The high frequency emission modules 303 may be substantially similar to the high frequency emission modules 103 described above with respect to FIG. 1A. For example, the high frequency emission modules 303 may each comprise a solid state power source 305, a thermal break 320, and an applicator 342. In an embodiment, high frequency electromagnetic radiation may be generated by the solid state power source 305 and transmitted to the antenna 343 of the applicator along a cable 365 that is electrically coupled to the antenna 343 by a connector 327 of the thermal break 320. In an embodiment, the thermal break 320 may comprise a housing 321 with an inner core 322 that includes a fluidic channel 323. A dielectric plug 324 may be provided around the antenna 343 that passes through a hole in the core 322.

In an embodiment, the modular high frequency emission source 304 may inject high frequency electromagnetic radiation into a chamber 378 through a dielectric window 375. The high frequency electromagnetic radiation may induce a plasma 390 in the chamber 378. The plasma 390 may be used to process a substrate 374 that is positioned on a support 376 (e.g., an electrostatic chuck (ESC) or the like). In some embodiments, the support 376 may be rotatable in order to improve on-substrate 374 uniformity during processing.

Referring now to FIG. 3B, a cross-sectional illustration of a processing system 300 with a modular high frequency emission source 304 is shown, in accordance with an embodiment. In an embodiment, the modular high frequency emission source 304 in FIG. 3B may be similar to the modular high frequency emission source 304 in FIG. 3A, with the exception of the thermal break 320. Instead, a thermal break similar to the thermal break 220 in FIG. 2A is shown, in accordance with an embodiment. For example, the thermal break 320 may comprise a lower housing 351 that is coupled to an upper housing 353 in order to define a fluidic channel 355 around a tube 354 that passes through the upper housing 353 and the lower housing 351. In an embodiment, a dielectric plug 324 is within the tube 354, and the antenna 343 is inserted into the dielectric plug 324. In an embodiment, a mounting bracket 358 may be provided between the lower housing 351 and the applicator 342.

Referring now to FIG. 4, a schematic of a solid state power source 405 is shown, in accordance with an embodiment. In an embodiment, the solid state power source 405 comprises an oscillator module 406. The oscillator module 406 may include a voltage control circuit 410 for providing an input voltage to a voltage controlled oscillator 420 in order to produce high frequency electromagnetic radiation at a desired frequency. Embodiments may include an input voltage between approximately 1V and 10V DC. The voltage controlled oscillator 420 is an electronic oscillator whose oscillation frequency is controlled by the input voltage. According to an embodiment, the input voltage from the voltage control circuit 410 results in the voltage controlled oscillator 420 oscillating at a desired frequency. In an embodiment, the high frequency electromagnetic radiation may have a frequency between approximately 0.1 MHz and 30 MHz. In an embodiment, the high frequency electromagnetic radiation may have a frequency between approximately 30 MHz and 300 MHz. In an embodiment, the high frequency electromagnetic radiation may have a frequency between approximately 300 MHz and 1 GHz. In an embodiment, the high frequency electromagnetic radiation may have a frequency between approximately 1 GHz and 300 GHz.

According to an embodiment, the electromagnetic radiation is transmitted from the voltage controlled oscillator 420 to an amplification module 430. The amplification module 430 may include a driver/pre-amplifier 434, and a main power amplifier 436 that are each coupled to a power supply 439. According to an embodiment, the amplification module 430 may operate in a pulse mode. For example, the amplification module 430 may have a duty cycle between 1% and 99%. In a more particular embodiment, the amplification module 430 may have a duty cycle between approximately 15% and 50%.

In an embodiment, the electromagnetic radiation may be transmitted to the thermal break 450 and the applicator 442 after being processed by the amplification module 430. However, part of the power transmitted to the thermal break 450 may be reflected back due to the mismatch in the output impedance. Accordingly, some embodiments include a detector module 481 that allows for the level of forward power 483 and reflected power 482 to be sensed and fed back to the control circuit module 421. It is to be appreciated that the detector module 481 may be located at one or more different locations in the system. In an embodiment, the control circuit module 421 interprets the forward power 483 and the reflected power 482, and determines the level for the control signal 485 that is communicatively coupled to the oscillator module 406 and the level for the control signal 486 that is communicatively coupled to the amplifier module 430. In an embodiment, control signal 485 adjusts the oscillator module 406 to optimize the high frequency radiation coupled to the amplification module 430. In an embodiment, control signal 486 adjusts the amplifier module 430 to optimize the output power coupled to the applicator 442 through the thermal break 450. In an embodiment, the feedback control of the oscillator module 406 and the amplification module 430, in addition to the tailoring of the impedance matching in the thermal break 450 may allow for the level of the reflected power to be less than approximately 5% of the forward power. In some embodiments, the feedback control of the oscillator module 406 and the amplification module 430 may allow for the level of the reflected power to be less than approximately 2% of the forward power.

Accordingly, embodiments allow for an increased percentage of the forward power to be coupled into the processing chamber 478, and increases the available power coupled to the plasma. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator. Furthermore, the mechanical motion may not be as precise as the change in frequency that may be provided by a voltage controlled oscillator 420.

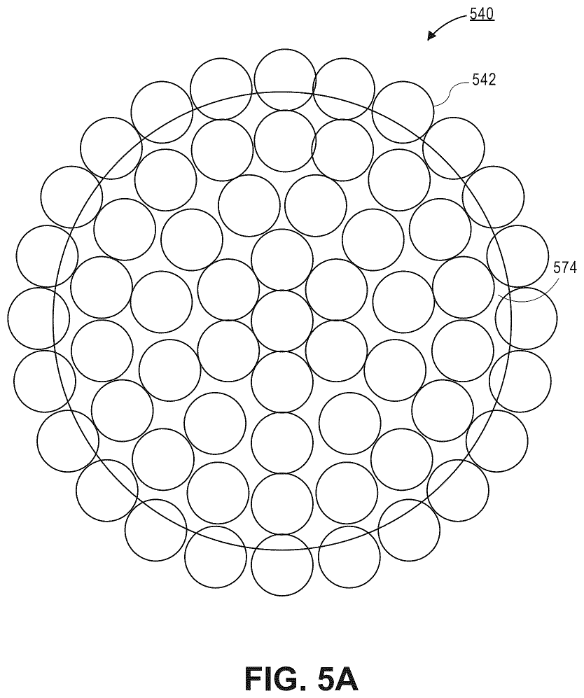

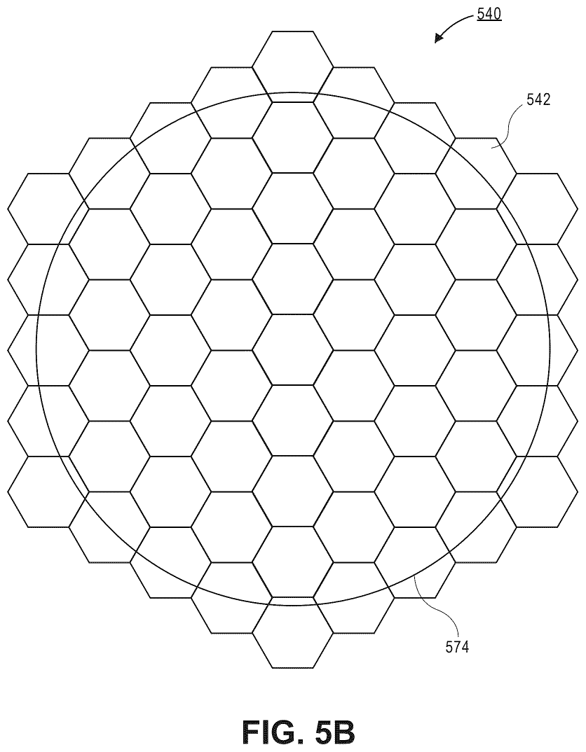

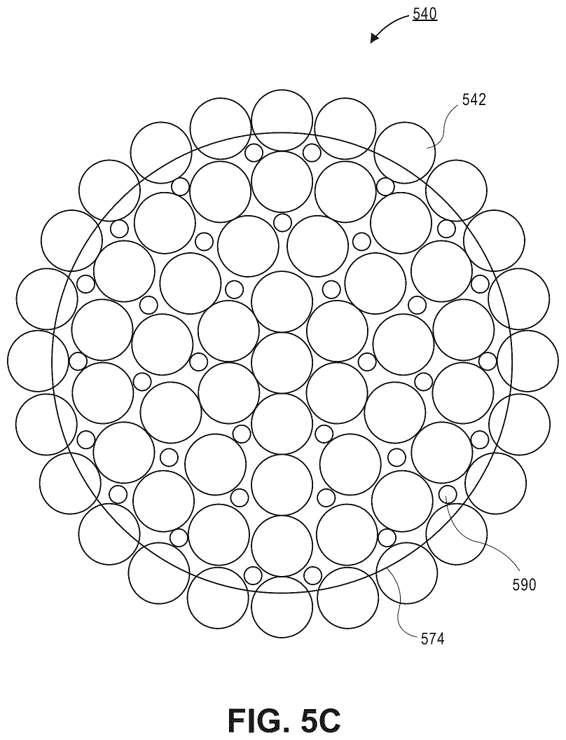

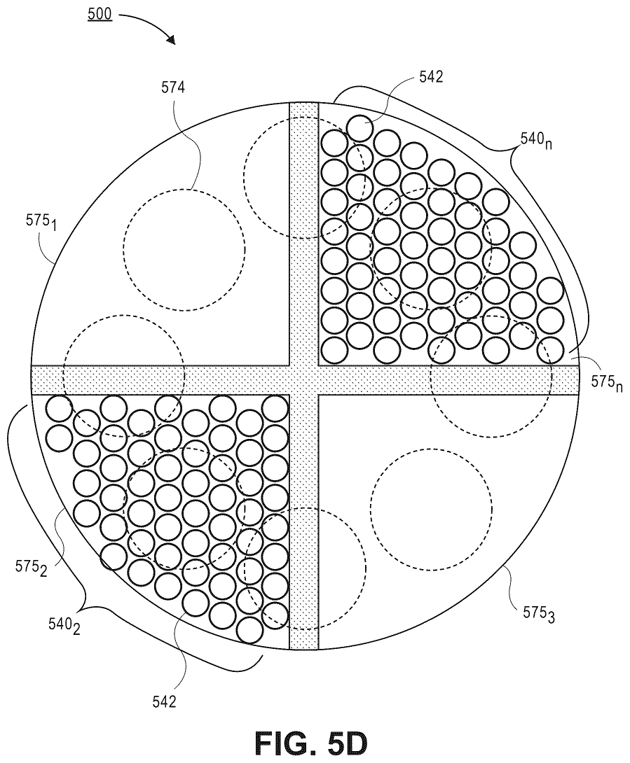

Referring now to FIG. 5A a plan view illustration of an array 540 of applicators 542 that are arranged in a pattern that matches a circular substrate 574 is shown, in accordance with an embodiment. By forming a plurality of applicators 542 in a pattern that roughly matches the shape of the substrate 574, the radiation field and/or plasma becomes tunable over the entire surface of the substrate 574. For example, each of the applicators 542 may be controlled so that a plasma with a uniform plasma density across the entire surface of the substrate 574 is formed and/or a uniform radiation field across the entire surface of the substrate 574 is formed. Alternatively, one or more of the applicators 542 may be independently controlled to provide plasma densities that are variable across the surface of the substrate 574. As such, incoming nonuniformity present on the substrate may be corrected. For example, the applicators 542 proximate to an outer perimeter of the substrate 574 may be controlled to have a different power density than applicators proximate to the center of the substrate 574. Furthermore, it is to be appreciated that the use of high frequency emission modules that allows for the emission of electromagnetic radiation that is at different frequencies and does not have a controlled phase relationship in order eliminate the existence of standing waves and/or unwanted interference patterns.

In FIG. 5A, the applicators 542 in the array 540 are packed together in a series of concentric rings that extend out from the center of the substrate 574. However, embodiments are not limited to such configurations, and any suitable spacing and/or pattern may be used depending on the needs of the processing tool. Furthermore, embodiments allow for applicators 542 with any symmetrical cross-section. Accordingly, the cross-sectional shape chosen for the applicator may be chosen to provide enhanced packing efficiency.

Referring now to FIG. 5B, a plan view of an array 540 of applicators 542 with a non-circular cross-section is shown, according to an embodiment. The illustrated embodiment includes applicators 542 that have hexagonal cross-sections. The use of such an applicator may allow for improved packing efficiency because the perimeter of each applicator 542 may mate nearly perfectly with neighboring applicators 542. Accordingly, the uniformity of the plasma may be enhanced even further since the spacing between each of the applicators 542 may be minimized. While FIG. 5B illustrates neighboring applicators 542 sharing sidewall surfaces, it is to be appreciated that embodiments may also include non-circular symmetrically shaped applicators that include spacing between neighboring applicators 542.

Referring now to FIG. 5C, an additional plan-view illustration of an array 540 of applicators 542 is shown according to an embodiment. The array 540 in FIG. 5C is substantially similar to the array 540 described above with respect to FIG. 5A, except that a plurality of sensors 590 are also included. The plurality of sensors provides improved process monitoring capabilities that may be used to provide additional feedback control of each of the modular high frequency power sources 405. In an embodiment, the sensors 590 may include one or more different types of sensors 590, such as plasma density sensors, plasma emission sensors, radiation field density sensors, radiation emission sensors, or the like. Positioning the sensors across the surface of the substrate 574 allows for the radiation field and/or plasma properties at given locations of the processing chamber to be monitored.

According to an embodiment, every applicator 542 may be paired with a different sensor 590. In such embodiments, the output from each sensor 590 may be used to provide feedback control for the respective applicator 542 to which the sensor 590 has been paired. Additional embodiments may include pairing each sensor 590 with a plurality of applicators 542. For example, each sensor 590 may provide feedback control for multiple applicators 542 to which the sensor 590 is proximately located. In yet another embodiment, feedback from the plurality of sensors 590 may be used as a part of a multi-input multi-output (MIMO) control system. In such an embodiment, each applicator 542 may be adjusted based on feedback from multiple sensors 590. For example, a first sensor 590 that is a direct neighbor to a first applicator 542 may be weighted to provide a control effort to the first applicator 542 that is greater than the control effort exerted on the first applicator 542 by a second sensor 590 that is located further from the first applicator 542 than the first sensor 590.

Referring now to FIG. 5D, an additional plan-view illustration of an array 540 of applicators 542 positioned in a multi-zone processing tool 500 is shown, according to an embodiment. In an embodiment, the multi-zone processing tool 500 may include any number of zones. For example, the illustrated embodiment includes zones 575₁-575n. Each zone 575 may be configured to perform different processing operations on substrates 574 that are rotated through the different zones 575. As illustrated, a first array 540₂ is positioned in zone 575₂ and a second array 540ₙ is positioned in zone 575ₙ. However, embodiments may include multi-zone processing tools 500 with an array 540 of applicators 542 in one or more of the different zones 575, depending on the needs of the device. The spatially tunable density of the plasma and/or radiation field provided by embodiments allows for the accommodation of nonuniform radial velocity of the rotating substrates 574 as they pass through the different zones 575.

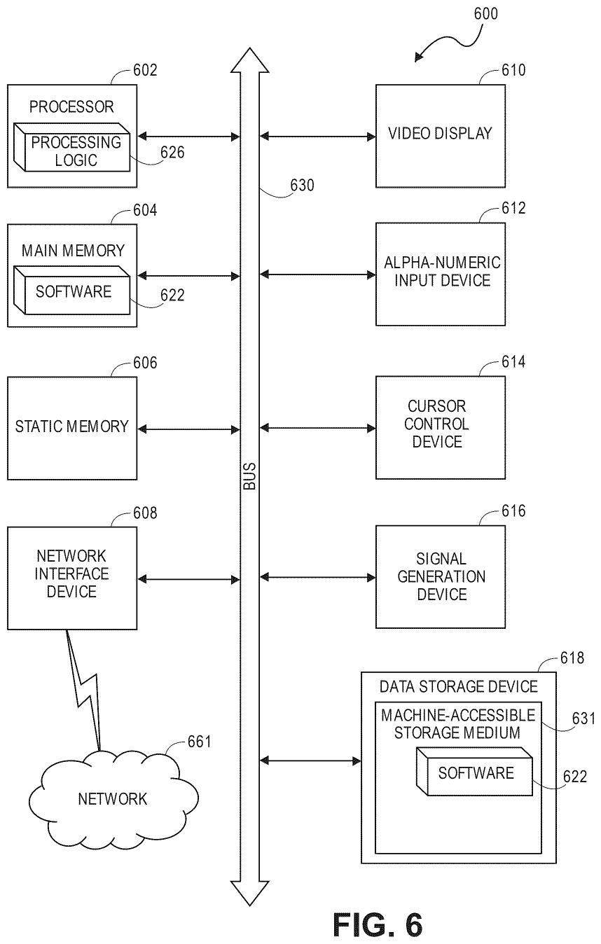

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a housing;
a core within the housing, wherein a channel is set into an outer surface of the core, and wherein a first hole passes through the core;
an inlet through the housing, wherein the inlet is fluidly coupled to the channel;
an outlet through the housing, wherein the outlet is fluidly coupled to the channel; and
a dielectric plug within the first hole, wherein a second hole passes through the dielectric plug.

2. The apparatus of claim 1, wherein the housing comprises a first metal and the core comprises a second metal that is different than the first metal.

3. The apparatus of claim 2, wherein the second metal comprises aluminum.

4. The apparatus of claim 1, wherein an outer diameter of the dielectric plug is non-uniform through a height of the dielectric plug.

5. The apparatus of claim 4, wherein the outer diameter of the dielectric plug is tapered.

6. The apparatus of claim 1, further comprising:
a mounting bracket on the housing.

7. The apparatus of claim 1, wherein the dielectric plug comprises polytetrafluoroethylene (PTFE), polyether ether ketone (PEEK), polyimide, perfluoroalkoxy alkane (PFA), polyetherimide (PEI), or polyvinylidene fluoride (PVDF).

8. The apparatus of claim 1, further comprising:
a metallic rod within the second hole.

9. An apparatus, comprising:
an upper housing with an interior tube;
a lower housing coupled to the upper housing, wherein the lower housing comprises an opening through the lower housing, wherein the interior tube passes through the opening, and wherein the upper housing and the lower housing define a channel around the interior tube; and
a dielectric plug within the interior tube, wherein a hole passes through the dielectric plug.

10. The apparatus of claim 9, wherein the lower housing is welded to the upper housing.

11. The apparatus of claim 9, further comprising:
a mounting bracket coupled to the lower housing.

12. The apparatus of claim 9, wherein the dielectric plug comprises an outer diameter through a height of the dielectric plug that is non-uniform.

13. The apparatus of claim 12, wherein the outer diameter of the dielectric plug is tapered.

14. The apparatus of claim 9, further comprising:
an inlet through the upper housing that is fluidly coupled to the channel; and
an outlet through the upper housing that is fluidly coupled to the channel.

15. The apparatus of claim 9, wherein the dielectric plug comprises polytetrafluoroethylene (PTFE), polyether ether ketone (PEEK), polyimide, perfluoroalkoxy alkane (PFA), polyetherimide (PEI), or polyvinylidene fluoride (PVDF).

16. The apparatus of claim 9, further comprising:
a metallic rod within the hole.

17. An apparatus, comprising:
a solid state high frequency power source;
an applicator for propagating high frequency electromagnetic radiation from the solid state high frequency power source; and
a thermal break coupled between the solid state high frequency power source and the applicator, wherein the thermal break comprises:
a housing with a fluidic channel;
a dielectric plug within the housing, wherein the dielectric plug is surrounded by the fluidic channel; and
a metallic rod through the dielectric plug, wherein the metallic rod electrically couples the solid state high frequency power source to the applicator.

18. The apparatus of claim 17, wherein the housing comprising:
an outer housing; and
a core within the outer housing, wherein the fluidic channel is set into an outer surface of the core, and wherein the outer housing seals the fluidic channel.

19. The apparatus of claim 17, wherein the housing comprises:
a lower housing with a hole through the lower housing; and
an upper housing coupled to the lower housing, wherein a tube of the upper housing passes through the hole, and wherein the dielectric plug is within the tube.

20. The apparatus of claim 17, further comprising:
an inlet through the housing and fluidically coupled to the fluidic channel; and
an outlet through the housing and fluidically coupled to the fluidic channel.
